(19) United States
(12) Patent Application Publication
(10) Pub. No.: US 2013/0264687 A1
(43) Pub. Date: Oct. 10, 2013

(54) METHOD FOR PRODUCING COLUMNAR STRUCTURE

(71) Applicant: CANON KABUSHIKI KAISHA, Tokyo (JP)

(72) Inventor: Makoto Koto, Yokohama-shi (JP)

(73) Assignee: CANON KABUSHIKI KAISHA, Tokyo (JP)

(21) Appl. No.: 13/841,032

(22) Filed: Mar. 15, 2013

(30) Foreign Application Priority Data
Apr. 9, 2012 (JP) 2012-088821

(51) Int. Cl. H01L 21/02; H01L 29/06

(52) U.S. Cl. CPC H01L 21/02491; H01L 29/0684
USPC 257/618; 438/478

(57) ABSTRACT

A method for producing a semiconductor includes a step of preparing a substrate having a fixing portion, a step of disposing a catalyst on the fixing portion, and a step of growing a semiconductor between the catalyst and the fixing portion, wherein a eutectic temperature between the catalyst and the semiconductor is lower than that between the fixing portion and the substrate.

### BACKGROUND OF THE INVENTION

1. Field of the Invention

The present invention relates to a method for producing a columnar structure.

2. Description of the Related Art

Semiconductor nanowires attract attention because of the possibility of producing transistors with good transconductance characteristics. In addition, attention is paid to application to sensors because of very high surface/volume ratios.

Examples of a technique for forming nanowires include a top-down method using lithography and etching, and a bottom-up method such as a VLS (vapor-liquid-solid) method.

The use of the bottom-up method can produce nanowires having a small cross section with a small diameter and a low crystal defect density. Such nanowires cannot be easily formed by using the top-down method.

A VLS growth method which is one of the bottom-up method is a method of forming a eutectic state between a catalyst metal and a semiconductor specifies, and precipitating the semiconductor species supersaturated by further supplying the semiconductor species, thereby allowing the growth of a structure to proceed.

Wires having high crystallinity and shape reproducibility can be formed by using the VLS method. However, VLS growth using a catalyst formed on a single-crystal substrate easily causes aggregation of eutectic droplets of the catalyst metal and the semiconductor species, and diffusion and displacement of the droplets on the substrate.

Since the diameter of nanowires comes close to the diameter of the droplets at the start of growth, variation occurs in diameter of the nanowires after growth due to aggregation and diffusion of the droplets.

In order to resolve the problem, Japanese Laid-Open Publication No. 2003-277200 discloses a technique for suppressing diffusion of a catalyst metal by H-terminating a surface of a Si substrate excluding a region where a catalyst is formed. Also, Japanese Laid-Open Publication No. 2006-239857 discloses a technique for suppressing aggregation of droplets by providing a texture on a substrate.

The production method disclosed in Japanese Laid-Open Publication No. 2003-277200 uses an electron beam for removing H and thus includes a complicated process and has low versatility. In addition, there is a restriction that the growth temperature of the structure is limited to be a H elimination temperature or less.

The production method disclosed in Japanese Laid-Open Publication No. 2006-239857 suppresses diffusion of the catalyst by providing the texture on the substrate, but diffusion from adjacent Au catalyst particles cannot be sufficiently suppressed only by providing the texture. With respect to this, it is described in Ferralis et. al, Physical Review Letters 103, 256102, 2009 that VLS growth using Si or Ge causes diffusion of Au used as a catalyst on a surface of a Si substrate.

Diffusion of Au in Si is undesirable because Au may become a source of noise because Au forms an electron source in the Si energy bandgap. The suppression of Au diffusion disclosed in the related techniques is unsatisfactory.

### SUMMARY OF THE INVENTION

The present invention provides a method for producing nanowires having little variation in diameter and length by providing a metal layer between a catalyst metal and a substrate in order to suppress aggregation and displacement of the catalyst.

Accordingly, the present invention provides a method for producing a semiconductor, the method including a step of preparing a substrate having a fixing portion, a step of disposing a catalyst on the fixing portion, and a step of growing a semiconductor between the catalyst and the fixing portion, wherein the eutectic temperature between the catalyst and the semiconductor is lower than the eutectic temperature between the fixing portion and the substrate.

Further features of the present invention will become apparent from the following description of exemplary embodiments with reference to the attached drawings.

### BRIEF DESCRIPTION OF THE DRAWINGS

FIGS. 1A to 1C are drawings illustrating a method for producing a columnar structure according to a first exemplary embodiment of the present invention.

FIG. 2 is a drawing illustrating a method for producing a columnar structure according to a second exemplary embodiment of the present invention.

FIG. 3 is a drawing illustrating a method for producing a columnar structure according to a third exemplary embodiment of the present invention.

FIG. 4 is a drawing illustrating a silicon columnar structure produced according to the first exemplary embodiment of the present invention.

FIG. 5 is a drawing illustrating the results of cross-sectional observation with a transmission electron microscope near an interface between a substrate and a silicon columnar structure produced according to the first exemplary embodiment of the present invention.

### DESCRIPTION OF THE EMBODIMENTS

The present invention relates to a method for producing a semiconductor, the method including, a step of preparing a substrate having a fixing portion, a step of disposing a catalyst on the fixing portion, and a step of growing a semiconductor between the catalyst and the fixing portion, wherein a eutectic temperature between the catalyst and the semiconductor is lower than the eutectic temperature between the fixing portion and the substrate.

In an exemplary embodiment of the present invention, the term “columnar structure” includes structures referred to as “nanowire”, “nanowhisker” and “whisker”.

In the exemplary embodiment, the fixing portion provided in contact with the catalyst can also be referred to as the “anti-diffusion layer” because it is adapted for suppressing diffusion of the catalyst on the substrate.

The fixing portion is provided in order to prevent displacement of the catalyst on the substrate. Therefore, the fixing portion can also be referred to as the “catalyst position fixing layer”.

Since the fixing portion is provided, the catalyst is fixed without being moved on the substrate. Therefore, the semiconductor having a desired diameter can be formed.

The fixing portion is made of a material which does not form a eutectic state with the catalyst at a temperature in the step of growing the semiconductor. The shape of the fixing portion is not particularly limited as long as it is made of such a material. Examples of the shape include a particle and a granular shape disposed on the substrate.

The eutectic temperature is uniquely determined from a relation between two substances and can be read from a phase diagram.

### First Embodiment

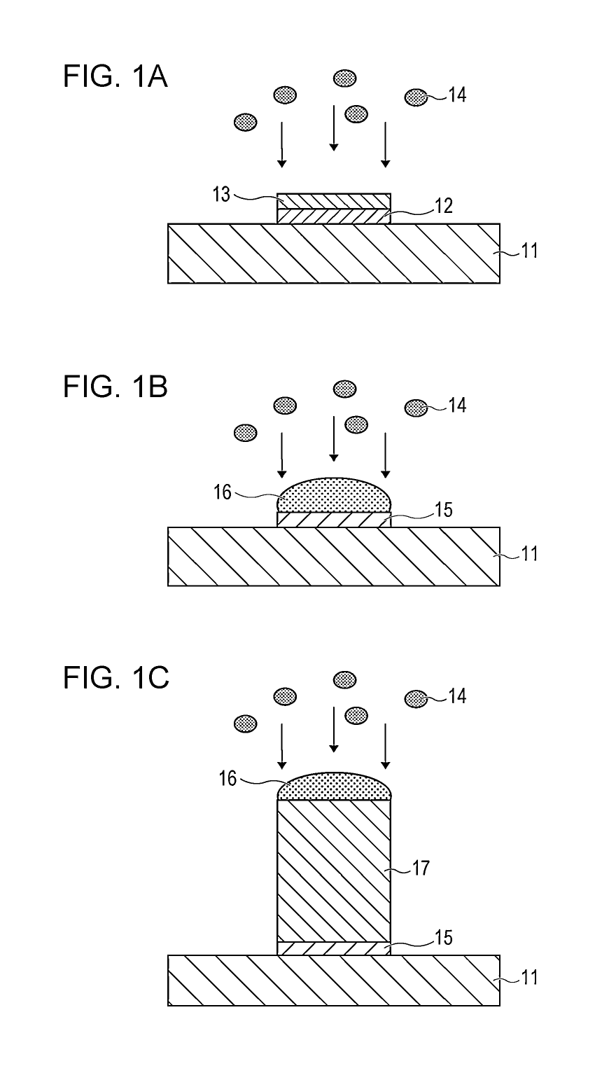

This embodiment is described with reference to FIGS. 1A to 1C.

FIG. 1A shows a step of forming a fixing portion 12 and a catalyst 13 to cover a portion of a substrate 11 so that the fixing portion 12 and the catalyst 13 cover the same region. In this step, a reaction species 14 is supplied.

The substrate 11 is made of a material having crystallinity and a difference in surface energy between plane orientations. More specifically, Si or the like can be used because it has high strength and planarity. When the substrate 11 has crystallinity, the columnar structure to be formed can be grown in a specified direction.

Further, the columnar structure can be epitaxially grown so that the plane orientation of the substrate is the same as that of the semiconductor constituting the columnar structure. The growth direction of the column can be controlled by epitaxial growth.

It is described in Schmidt et. al, Nano Letters, vol. 5, No. 5, 931-935, 2005 that when a columnar structure is formed on the substrate by a VLS method, a nanowire is grown in plane orientation with lower surface energy.

For example, when a columnar structure of Si having a diameter of 20 nm or more is formed, growth proceeds preferentially in <111> orientation. Therefore, when a columnar structure is desired to be grown perpendicularly to the substrate, a (111) Si substrate may be used.

A metal constituting the fixing portion 12 is a material which forms an alloy with the substrate 11, but not a material leading to a molten state in which it forms a eutectic with the substrate 11, within the growth temperature region of the columnar structure.

Specifically, Ti, V, Cr, Mn, Fe, Co, Ni, Cu, Zr, Nb, Mo, Tc, Ru, Rh, Pd, Hf, Ta, W, Re, Os, Ir, Pt, or the like can be used for the fixing portion. In order to properly form an alloy between the fixing portion and the catalyst during growth of the columnar structure, the thickness of the fixing portion 12 is preferably 1 nm or more and 50 nm or less and more preferably 1 nm or more and 10 nm or less.

Such a thin fixing portion 12 is desirable for decreasing the occurrence of peeling from a metal having large stress, such as Ti.

The fixing portion 12 is heat-treated so as to form an alloy with the substrate 11 at the same time or before introduction of the reaction species 14 described below and heating of the substrate 11. The alloy is formed between the fixing portion 12 and the catalyst 13.

For example, when Ti is used in the fixing portion, alloying is started by treatment at 300° C. or more. The conditions and time-series order of alloying and heat treatment to grow the columnar structure can be properly determined according to the materials of the catalyst 13 and the fixing portion 12, the thickness of each of them, etc.

The fixing portion 12 may be formed so as to avoid contact between the catalyst 13 and the substrate 11.

The catalyst 13 may be provided in contact with the fixing portion 12. When the substrate 11 is provided below the fixing portion 12, the catalyst 13 may be provided on at least a portion of the fixing portion 12.

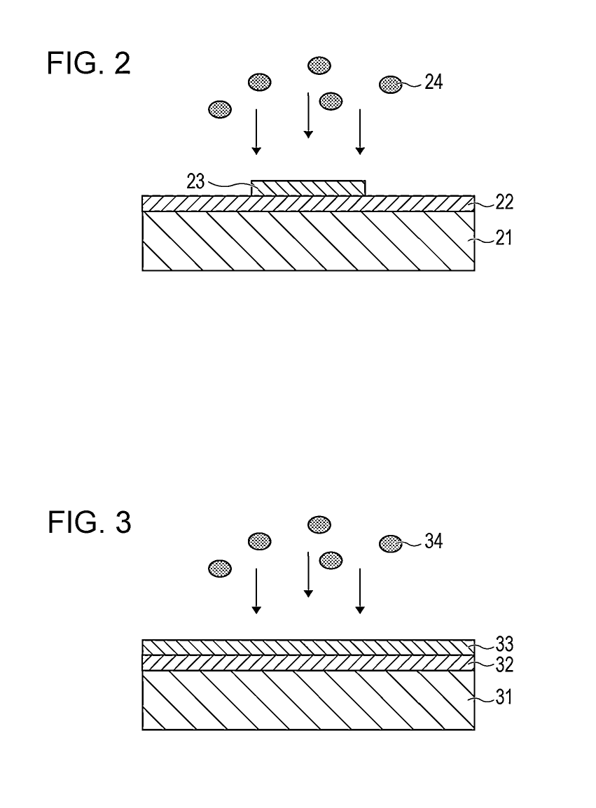

For example, as shown in FIG. 1A, the catalyst 13 and the fixing portion 12 may be provided to cover the same region. Alternatively, as shown in FIG. 2, only a region of a catalyst 23 may be limited, while a region of a fixing portion 22 may not be limited. Also, as shown in FIG. 3, regions of both a catalyst 33 and a fixing portion 32 may not be limited.

The catalyst 13 is selected from materials which form eutectics with the reaction species 14. For example, Au, Al, Sn, Pb, Bi, Fe, Ag, or the like can be used. The reaction species 14 is selected from Si, Ge, and compounds thereof.

A combination of Au used as the catalyst 13 and Si used as the reaction species 14 is a combination of materials which form a eutectic at a low temperature. Therefore, this combination is a desired example with a high degree of freedom of growth conditions for the columnar structure.

When the region of the catalyst 13 is limited, the diameter of the columnar structure to be formed can be controlled.

According to the exemplary embodiment, a plurality of fixing portions may be disposed in a plane of a substrate to be isolated from each other.

The advantage of the present invention can be achieved by any one of the above-described configurations. Further, any configuration may be used as long as the fixing portion is provided between the catalyst and the substrate.

FIGS. 1A, 2, and 3 show configurations different from each other with respect to the regions of the catalyst 13 and the fixing portion 12. In any one of the configurations, the columnar structure can be grown in the same manner as in FIGS. 1B and 1C except that the alloy is formed in a different region.

When the region of the catalyst 13 is limited as shown in FIGS. 1A to 1C and 2, the diameter of the columnar structure to be formed is determined by the diameter of the catalyst, and thus it is desirable to control the region and thickness of the catalyst.

The VLS growth method used in the exemplary embodiment can produce a columnar structure having a diameter of 10 nm to 200 nm. In view of this, the diameter of the region of the catalyst is 10 nm or more and 200 nm or less from the viewpoint of the lower limit of processing accuracy and layer formation.

The shape of the region of the catalyst is not limited to a circular shape. When the shape is not circular, the region of the catalyst may have an area corresponding to the above-described area.

When the region of the fixing portion 12 is limited as shown in FIGS. 1A to 1C, the catalyst 13 is processed to cover the same region as the fixing portion 12. When the region of the fixing portion 12 is limited as shown in FIG. 2, the region of only the catalyst 13 is limited.

When the regions of the catalyst 13 and the fixing portion 12 are limited in the same manner, both may be processed simultaneously or separately.

According to the exemplary embodiment, the fixing portion and the catalyst can be formed by a known lithography technique. For example, the processing accuracy can be achieved by using a stepper including a light source of i-line, KrF, ArF, F₂, or the like suitable for micro-size processing, or an electron beam drawing apparatus.

The above-described configurations can be formed by applying an etching process or a lift-off process to a lithography resist pattern formed as described above.

In addition, a technique of depositing a desired metal to a desired portion using an apparatus such as FIB (focus ion beam) or the like can be used.

In a columnar structure 17 shown in FIG. 1C, the composition of the columnar structure to be formed varies with the combination of the reaction species 14 and the catalyst 13. Examples of the composition of the columnar structure include a semiconductor, a metal, a dielectric material, and composites thereof.

Examples of the semiconductor include Si, Ge, SiGe, GaAs, InP, InGaAs, SiC, and the like. Examples of the catalyst include Au, Ag, Al, Zn, Ga, In, Sn, Tl, Pb, Bi, and the like. Examples of the dielectric material include SiO₂. SiN, HfO₂, Al₂O₂, and the like.

For example, when the columnar structure of silicon or germanium is formed, gas containing a constituent atom of the columnar structure, such as SiH₄, SiF₄, SiCl₄, SiHCl₂, SiH₂Cl₂, GeH₄, or the like, can be used as the reaction species 14. In addition, the reaction species can be supplied by a method such as PLD (pulsed laser deposition), sputtering, or the like.

Next, in the state shown in FIG. 1A, the substrate temperature is determined to a temperature at which the reaction species 14 is dissolved in the catalyst 13. For example, in growth of a silicon nanowire using Au as the catalyst, the temperature is higher than the eutectic temperature of 363° C.

The fixing portion 12 and the substrate 11 may form an alloy by the heat treatment or may form an alloy before the heat treatment.

As described above, a semiconductor species is dissolved in the catalyst by supplying a semiconductor raw material to form a melt droplet 16 in a eutectic state as shown in FIG. 1B. Further, the reaction species 14 is continuously supplied to supersaturate the composition ratio of the reaction species 14 in the metal droplet 16, thereby growing the columnar structure 17. That is, growth takes place due to a so-called VLS mechanism to form the columnar structure.

Diffusion of the catalyst on the substrate can be suppressed by forming the fixing portion. As a result, variation in diameter and height of the columnar structure to be formed can be suppressed.

When the fixing portion forms a crystalline alloy with the substrate, the columnar structure can be grown in specified plane orientation like in a configuration in which the catalyst is in direct contact with the substrate.

Further, when the alloy forms crystal orientation reflecting the crystal orientation of the substrate, the columnar structure can be grown in the same direction as in a configuration in which the catalyst is in direct contact with the substrate. Therefore, reproducibility of the diameter and length can be improved without impairing controllability of the growth orientation.

In the production method according to the exemplary embodiment, a carbon fiber can be produced by changing the semiconductor to carbon and using Fe or FeSi as the catalyst.

In the exemplary embodiment, the carbon fiber refers to a carbon nanotube such as SWCNT (single-walled carbon nanotube), MWCNT (multi-walled carbon nanotube), or the like, or a carbon fiber such as graphite nanofiber, or the like. It does not matter whether or not the carbon nanotube has a space at the center thereof.

A structure according to an exemplary embodiment of the present invention includes a substrate, a fixing portion provided on the substrate, and a semiconductor provided on the fixing portion.

In the structure, the melting point of the fixing portion is higher than that of the semiconductor.

The fixing portion is provided on a surface of the substrate.

The structure according to the exemplary embodiment includes the semiconductor which can be provided at a precise position in a plane of the substrate. Further, the semiconductor which extends out of the plane of the substrate can be extended in a desired direction, and thus semiconductors isolated from each other can be disposed without contact with each other.

In addition, the semiconductor provided in the structure according to the exemplary embodiment can be provided at a desired position in the plane of the substrate, and thus a desired shape can be formed by a set of semiconductors.

Examples of the desired shape include a circular shape, an elliptic shape, a triangular shape, a square shape, a rectangular shape, a star-like shape, and the like.

The semiconductor provided in the structure according to the exemplary embodiment may remain having the catalyst. In this case, the catalyst is disposed at one of the ends of the semiconductor, the other end being fixed to a fixing member. After the structure is produced, the catalyst may be removed to leave only the structure, or the catalyst may not be removed.

Examples of a method for removing the catalyst include a chemical treatment method of treating with an acid, an alkali, or the like, and a physical method of physically removing.

The semiconductor provided in the structure according to the exemplary embodiment can be removed from the structure.

The columnar structure according to the exemplary embodiment can be used for a device.

In use for a device, an example of a possible configuration is that in which the columnar structure is disposed in a gate portion of a sensor using a transistor. As the device, a known sensor device such as FET (field effect transistor) or the like can be used.

In addition, the columnar structure can be used, for example, in the form of a through wiring material in order to achieve interlayer conduction of a device having a three-dimensional structure.

The device including the columnar structure according to the exemplary embodiment is improved in production reproducibility of diameter and length of the columnar structure, thereby improving characteristics and output reproducibility. This is desirable from the viewpoint of device application.

The device including the columnar structure according to the exemplary embodiment is considered to have a structure having a high surface/volume ratio and produced with good reproducibility. Therefore, the device can be applied to a high-sensitivity sensor device having the structure in a sensor portion.

The sensor device includes a sensing portion and an electrode connected to the sensing portion, the sensing portion including the structure according to the embodiment. The sensor device can perform sensing when a measurement object adheres to the structure to cause a change in the electric characteristics of the object.

The electric characteristic to be changed is not particularly limited and may be a current characteristic, a voltage characteristic, or another characteristic.

Such a sensor device can be expected to detect with high sensitivity.

### Example 1

In this example, a method for forming a columnar structure at a predetermined position on a substrate is described with reference to FIGS. 1A to 1C. In this example, a Si substrate is used as the substrate.

First, a surface of the (111) Si substrate is washed with a liquid mixture of ammonia water and aqueous hydrogen peroxide to remove particles and further washed with a liquid mixture of hydrochloric acid and aqueous hydrogen peroxide to remove metal contaminants. That is, the Si substrate is washed by so-called RCA washing.

Then, the substrate is immersed in a 5% diluted hydrofluoric acid for 30 seconds to remove an oxide film. Then, the Si substrate is baked at 100° C. for 1 minute.

Next, the Si substrate is coated with a liquid containing electron beam resist ZEP520A (manufactured by Zeon Corporation) and electron beam resist thinner ZEP-A (manufactured by Zeon Corporation) at 1:1. In this case, spin coating is performed with a spin coater at 4000 rpm for about 1 minute to form a uniform resist coating of about 100 nm.

Then, a circular region of 40 nm in diameter at a desired position is irradiated with an electron beam in a dosage of 500 μC/cm². Then, development is performed with electron beam resist developer ZED-N50 (manufactured by Zeon Corporation) for 2 minutes, followed by rinsing with isopropyl alcohol for 1 minute and N₂ blowing to remove a circular resist of 40 nm in diameter at the irradiated position.

Then, the substrate is immediately introduced in an electron beam vapor deposition apparatus, and Ti and Au are deposited to thicknesses of 3 nm and 7 nm, respectively, in that order. Then, the substrate is immersed in electron beam resist peeling liquid ZDMAC for 3 minutes while ultrasonic waves are applied, and then similarly, the substrate is immersed in acetone and isopropyl alcohol for 3 minutes each under ultrasonic washing.

In the above-described steps, as shown in FIG. 1A, fixing portion Ti and catalyst Au are formed only in the same region on the (111) Si substrate.

Then, the substrate is transferred to a CVD (chemical vapor deposition) growth apparatus in which the substrate is annealed at 500° C. with Ar gas in a vacuum chamber to cause the Si substrate 11 and the Ti fixing portion 12 to form an alloy portion 15 as shown in FIG. 1B. Although FIG. 1B shows a state in which the fixing portion is entirely alloyed, an unalloyed metal may remain.

Further, a reaction species 14 is introduced using silane gas. As a result, Au of the catalyst 13 and Si of the reaction species 14 are melted in a eutectic state to form a droplet 16. When the reaction species 14 is further supplied, a supersaturated portion of the semiconductor species 14 is precipitated downward from the droplet 16 to form the columnar structure 17 by the so-called VLS process.

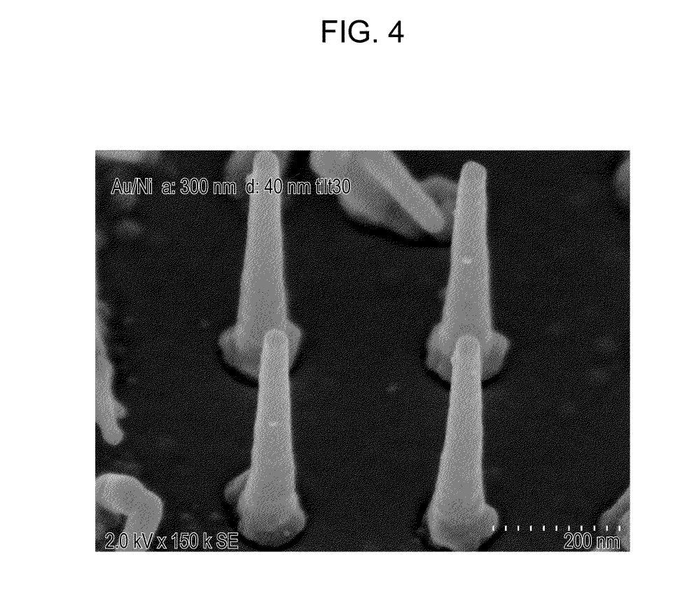

Growth positions shown in FIG. 4 can be controlled by introducing the silane gas under the above-described conditions, thereby forming silicon columnar structures of nano-sizes with little variation in length and diameter.

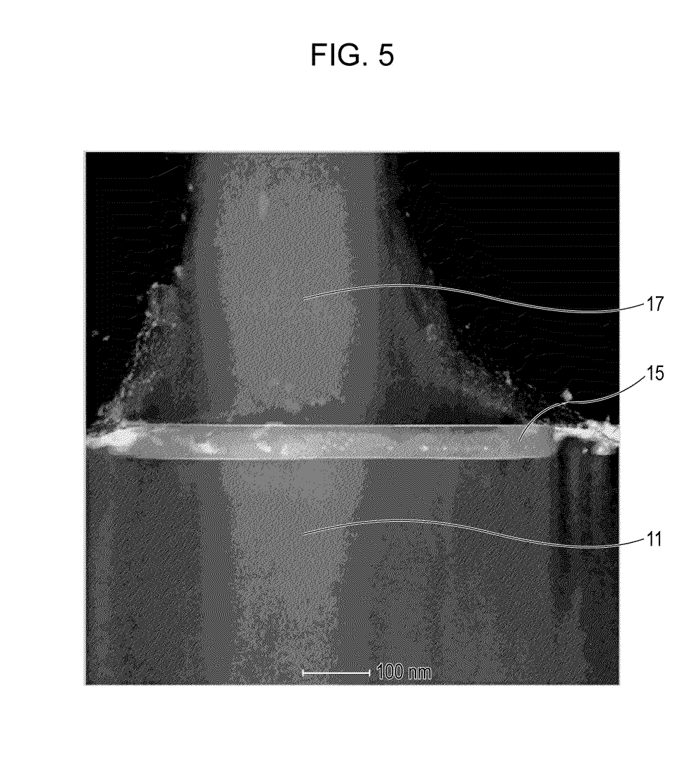

FIG. 5 shows results of cross-sectional observation with a transmission electron microscope at an interface between a silicon substrate and a silicon columnar structure grown under the above-described conditions. It can be confirmed that a silicon-Ti alloy portion is formed between the silicon columnar structure and the silicon substrate.

### Example 2

This example is described with reference to FIG. 2. This example is the same as Example 1 except that the fixing portion 22 is formed over the entire surface of a substrate. First, Ti is deposited to a thickness of 3 nm over the entire surface of a Si substrate 21 washed by the same method as in Example 1, forming the fixing portion 22. Then, Au of 7 nm in thickness is formed as the catalyst 23 in a circular region of 40 nm in diameter by the same electron beam drawing as in Example 1.

Then, the substrate is heated, and the reaction species 24 is introduced in the same manner as in Example 1, forming a columnar structure at a desired position by the same method as in Example 1 except a region where an alloy portion is formed.

### Example 3

This example is described with reference to FIG. 3. This example is the same as Example 1 except that the fixing portion 32 and the catalyst 33 are formed over the entire surface of a substrate.

First, Ti and Au are deposited to 3 nm and 7 nm, respectively, over the entire surface of a Si substrate 31 washed by the same method as in Example 1, forming the fixing portion 32 and the catalyst 33.

Then, the substrate is heated, and the reaction species 34 is introduced in the same manner as in Example 1 to form a molten droplet on an alloy portion, thereby forming a columnar structure.

In Example 3, unlike in Examples 1 and 2, it is difficult to control the position of the columnar structure, but it is possible to achieve the effect of suppressing aggregation of the catalyst and suppressing diffusion of the catalyst layer into the substrate.

In view of application to a device, it is desirable to suppress variation of the diameter, and a structure produced by the production method according to the embodiment of the present invention can be applied to a device.

In particular, in use for a sensing device, a nano-wire has a constant diameter, and thus a sensing device with small measurement error can be produced.

Assuming that the produced nano-wire is directly incorporated into a device, Example 1 or 2 can be employed because it is desired to control the growth position.

According to the present invention, it is possible to provide a method for forming a nano-wire with little variation in diameter and length, in which a fixing portion is provided between a catalyst and a substrate, and, a eutectic temperature between the substrate and fixing portion is higher than that between the catalyst and the reaction species, and the catalyst and the substrate are spatially separated, thereby suppressing displacement of the catalyst and aggregation of the catalyst.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-088821 filed Apr. 9, 2012, which is hereby incorporated by reference herein in its entirety.

What is claimed is:

1. A method for producing a semiconductor, comprising:
a step of preparing a substrate having a fixing portion;
a step of disposing a catalyst on the fixing portion; and
a step of growing a semiconductor between the catalyst and the fixing portion,
wherein a eutectic temperature between the catalyst and the semiconductor is lower than that between the fixing portion and the substrate.

2. The method for producing a semiconductor according to claim 1, wherein a eutectic temperature between the catalyst and the fixing portion is higher than that between the catalyst and the semiconductor.

3. The method for producing a semiconductor according to claim 1, wherein a melting point of the fixing portion is higher than that of the catalyst.

4. The method for producing a semiconductor according to claim 1, wherein the fixing portion is composed of a particle disposed on a surface of the substrate.

5. The method for producing a semiconductor according to claim 1,
wherein the semiconductor contains at least one selected from the group consisting of Si, Ge, SiGe, GaAs, InP, InGaAs, and SiC;
the catalyst contains at least one selected from the group consisting of Au, Ag, Al, Zn, Ga, In, Sn, Tl, Pb, and Bi; and
the fixing portion contains at least one selected from the group consisting of Ti, V, Cr, Mn, Fe, Co, Ni, Cu, Zr, Nb, Mo, Tc, Ru, Rh, Pd, Hf, Ta, W, Re, Os, Ir, and Pt.

6. The method for producing a semiconductor according to claim 5,
wherein the semiconductor contains Si;
the catalyst contains Au; and
the fixing portion contains Ti.

7. The method for producing a semiconductor according to claim 1, wherein a plurality of the fixing portions are provided in a plane of the substrate to be isolated from each other.

8. A structure comprising:
a substrate;
a fixing portion provided on the substrate; and
a semiconductor disposed on the fixing portion,
wherein a melting point of the fixing portion is higher than that of the semiconductor.

9. A structure comprising:
a substrate;
a fixing portion provided on the substrate; and
a semiconductor disposed on the fixing portion,
wherein a catalyst is provided at one of the ends of the semiconductor;
the other end of the semiconductor is fixed to the fixing portion provided on a surface of the substrate; and
a eutectic temperature between the catalyst and the semiconductor is lower than that between the fixing portion and the substrate.

10. The structure according to claim 9, wherein a eutectic temperature between the catalyst and the fixing portion is higher than that between the catalyst and the semiconductor.

11. The structure according to claim 8,
wherein the semiconductor contains at least one selected from the group consisting of Si, Ge, SiGe, GaAs, InP, InGaAs, and SiC; and
the fixing portion contains at least one selected from the group consisting of Ti, V, Cr, Mn, Fe, Co, Ni, Cu, Zr, Nb, Mo, Tc, Ru, Rh, Pd, Hf, Ta, W, Re, Os, Ir, and Pt.

12. The structure according to claim 11,
wherein the semiconductor contains Si; and
the fixing portion contains Ti.

13. The structure according to claim 9,
wherein the semiconductor contains at least one selected from the group consisting of Si, Ge, SiGe, GaAs, InP, InGaAs, and SiC;
the catalyst contains at least one selected from the group consisting of Au, Ag, Al, Zn, Ga, In, Sn, Tl, Pb, and Bi; and
the fixing portion contains at least one selected from the group consisting of Ti, V, Cr, Mn, Fe, Co, Ni, Cu, Zr, Nb, Mo, Tc, Ru, Rh, Pd, Hf, Ta, W, Re, Os, Ir, and Pt.

14. The structure according to claim 13,
wherein the semiconductor contains Si;
the catalyst contains Au; and
the fixing portion contains Ti.

15. The structure according to claim 8, wherein a plurality of the semiconductors are disposed to be isolated from each other.

16. The structure according to claim 9, wherein a plurality of the semiconductors disposed to be isolated from each other.

17. A sensor device comprising:
a sensing portion; and
an electrode connected to the sensing portion,
wherein a measurement object is brought close to or in contact with the sensing portion to cause a change in an electric characteristic; and
the sensing portion includes the structure according to claim 8.

18. A sensor device comprising:
a sensing portion; and
an electrode connected to the sensing portion,
wherein a measurement object is brought close to or in contact with the sensing portion to cause a change in an electric characteristic; and
the sensing portion includes the structure according to claim 9.
